(19) United States
(12) Patent Application Publication
(10) Pub. No.: US 2008/0227273 A1
(43) Pub. Date: Sep. 18, 2008

(54) METHOD FOR MANUFACTURING SEMICONDUCTOR DEVICE

(75) Inventor: Hirokazu HISAMATSU, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/048,844

(22) Filed: Mar. 14, 2008

(30) Foreign Application Priority Data
Mar. 16, 2007 (JP) 2007-068237

(51) Int. Cl. H01L 21/20

(52) U.S. Cl. 438/479; 257/E21.09

(57) ABSTRACT

A method for manufacturing a semiconductor device includes: a) forming a first semiconductor layer on a semiconductor substrate; b) forming a second semiconductor layer on the first semiconductor layer; c) forming a first groove exposing a side of the first semiconductor layer by partially etching the first semiconductor layer and the second semiconductor layer; d) forming a cavity between the semiconductor substrate and the second semiconductor layer by etching the first semiconductor layer through the first groove under an etching condition in which the first semiconductor layer is more easily etched than the second semiconductor layer; e) respectively forming a third semiconductor layer on an upper surface of the semiconductor substrate and a lower surface of the second semiconductor layer that are facing an inside of the cavity while leaving a space in the cavity; and f) thermally oxidizing the third semiconductor layer so as to form a buried oxide film in the cavity.

The entire disclosure of Japanese Patent Application No. 2007-068237, filed Mar. 16, 2007 is expressly incorporated by reference herein.

### BACKGROUND

1. Technical Field

The present invention relates to a method for manufacturing a semiconductor device, and particularly relates to a technique to form a silicon-on-insulator (SOI) structure on a semiconductor substrate.

2. Related Art

To enhance performance of a semiconductor device, it has been attempted to form a transistor on a thin film silicon layer (hereinafter, also referred to as an SOI layer) formed on an insulating film with an aim of manufacturing a semiconductor integrated circuit having a circuit element isolated by a dielectric material and having a small stray capacitance. Further, examples of a technique to form the SOI structure at a required position on a bulk Si substrate are disclosed in JP-A-2005-354024 and Separation by Bonding Si islands (SBSI) for LSI Applications. (T, Sakai et al.), Second International SiGe Technology and Device Meeting, Meeting Abstract, pp. 230-231, May (2004).

The method disclosed in these examples is called the SBSI method. In the SBSI method, a Si layer and a SiGe layer are formed on a Si substrate, and only the SiGe layer is selectively removed by using difference of an etching rate between Si and SiGe so as to form a cavity between the Si substrate and the Si layer. Next, an upper surface of the Si substrate and a lower surface of the Si layer facing the inside of the cavity are thermally oxidized so that a SiO₂ film (hereinafter, also referred to as a BOX layer) is formed between the Si substrate and the Si layer. Then, SiO₂ or the like is deposited on the Si substrate by chemical vapor deposition (CVD), and planarized by chemical mechanical polishing (CMP), and further, etched by a diluted hydrofluoric acid (HF) solution or the like so as to expose a surface of the Si layer (hereinafter, also called as an SOI layer) on the BOX layer.

According to the method as above, a manufacturing cost that is a major issue for an SOI device can be reduced while an SOI transistor and a bulk transistor are allowed to be mounted in combination. As a result, a chip area can be reduced while advantages of both the SOI transistor and the bulk transistor are maintained.

FIG. 7 is a diagram showing an example of a sectional view according to the SBSI method in related art described above.

As shown in FIG. 7, in forming a BOX layer 131, an upper surface of a Si substrate 101 and a lower surface of a Si layer 105 (hereinafter, also referred to as the SOI layer 105) that are facing the inside of a cavity are thermally oxidized, thereby growing a SiO₂ film 131a from the Si substrate 101 while growing a SiO₂ film 131b from the Si layer 105. Then, these SiO₂ films 131a and 131b are attached to each other at about a center in a height direction in the cavity (hereinafter, simply referred to as “at about the center of the cavity”), forming the BOX layer 131.

However, this method has a difficulty in completely attaching the SiO₂ films 131a and 131b to each other, thereby easily causing a gap S remaining at an interface of the films. Further this incomplete attachment causes detachment of the SiO₂ film 131b from the SiO₂ film 131a in a later step (such as CMP to expose a surface of the SOI layer 105, wet etching with a dilute HF solution, and the like), causing a risk of detachment of the SOI layer 105 formed on the SiO₂ film 131b from the Si substrate 101 by accompanying with the SiO₂ film 131b.

Here, according to investigation results up to now, the inventor has concluded in that the incomplete attachment is caused by roughness of each surface of the SiO₂ films 131a and 131b.

That is, in the SBSI method as above, it was found that when the SiGe layer is etched with a hydrofluoric-nitric acid solution, surface roughnesses of Si substrate 101 and the Si layer 105 become large. Further, it was found that when each surface of the Si substrate 101 and the Si layer 105 is thermally oxidized while having a large surface roughness, each surface of the SiO₂ films 131a and 131b inherits the large surface roughness. Therefore, the inventor has concluded in that the surfaces of the SiO₂ films 131a and 131b are attached nearly by point contact rather than by surface contact in the forming the BOX layer 131, so that the contact area is small, causing easy detachment of the SiO₂ films 131a and 131b from each other.

### SUMMARY

An advantage of the present invention is to provide a method for manufacturing a semiconductor device that can improve adherence of buried oxide films growing from upper and lower directions in a cavity, and further, to provide a method for manufacturing a semiconductor device with high reliability.

A method for manufacturing a semiconductor device according to an aspect of the invention, includes: a) forming a first semiconductor layer on a semiconductor substrate; b) forming a second semiconductor layer on the first semiconductor layer; c) forming a first groove exposing a side of the first semiconductor layer by partially etching the first semiconductor layer and the second semiconductor layer; d) forming a cavity between the semiconductor substrate and the second semiconductor layer by etching the first semiconductor layer through the first groove under an etching condition in which the first semiconductor layer is more easily etched than the second semiconductor layer; e) respectively forming a third semiconductor layer on an upper surface of the semiconductor substrate and a lower surface of the second semiconductor layer that are facing the inside of the cavity while leaving a space in the cavity; and f) thermally oxidizing the third semiconductor layer so as to form a buried oxide film in the cavity.

The method according to the aspect of the invention may further include: partially etching the second semiconductor layer and the first semiconductor layer so as to form a second groove penetrating the second semiconductor layer and the first semiconductor layer; and forming a support to support the second semiconductor layer at least in the second groove between the step b) and the step d).

In this case, the step f) may further include thermally oxidizing the upper surface of the semiconductor substrate and the lower surface of the second semiconductor layer that are covered with the third semiconductor layer so as to form the buried oxide film in addition to thermally oxidizing the third semiconductor layer.

In this case, the semiconductor substrate may be made of silicon, and the step b) may include forming a first silicon layer having a single crystalline structure by epitaxial growth as the second semiconductor layer, while the step e) may include forming a second silicon layer having one of an amorphous structure and a polycrystalline structure by chemical vapor deposition (CVD) as the third semiconductor layer.

Here, the CVD described in the invention includes low pressure (LP) CVD, atmospheric pressure (AP) CVD, plasma (P) CVD and the like.

According to the aspect of the invention as above, the upper surface of the semiconductor substrate and the lower surface of the second semiconductor layer are covered with the third semiconductor layer having a small surface roughness in the cavity. Therefore, in the forming the buried oxide film, the third semiconductor layer is thermally oxidized first to be a surface of the buried oxide film. Accordingly, surface roughnesses of both the buried oxide film growing upward from the semiconductor substrate and the buried oxide film growing downward from the second semiconductor layer are reduced, resulting in favorable attachment of the buried oxide films growing from the upper and lower directions in the cavity. Therefore, the second semiconductor layer formed on the buried oxide film is prevented from being detached.

Consequently, a method for manufacturing a semiconductor device with high reliability can be provided.

Further, according to the method above, a portion having a large roughness is included in the buried oxide film by thermal oxidation, reducing dangling-bonds at an interface between the Si and SiO₂, and contributing to reducing an interface state density in the semiconductor substrate and the second semiconductor layer

### BRIEF DESCRIPTION OF THE DRAWINGS

The invention will be described with reference to the accompanying drawings, wherein like numbers reference like elements.

FIGS. 1A and 1B are diagrams illustrating a method for manufacturing a semiconductor device according to an embodiment.

FIGS. 2A and 2B are diagrams illustrating the method for manufacturing a semiconductor device according to the embodiment.

FIGS. 3A and 3B are diagrams illustrating the method for manufacturing a semiconductor device according to the embodiment.

FIGS. 4A and 4B are diagrams illustrating the method for manufacturing a semiconductor device according to the embodiment.

FIGS. 5A and 5B are diagrams illustrating the method for manufacturing a semiconductor device according to the embodiment.

FIGS. 6A and 6B are diagrams illustrating the method for manufacturing a semiconductor device according to the embodiment.

FIG. 7 is a sectional view illustrating an example of a method for manufacturing a semiconductor device in related art.

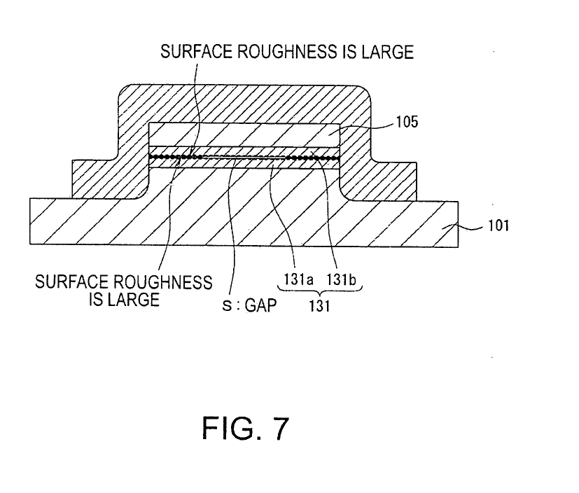

### DESCRIPTION OF EXEMPLARY EMBODIMENTS

An embodiment of the invention will now be described with reference to the accompanying drawings.

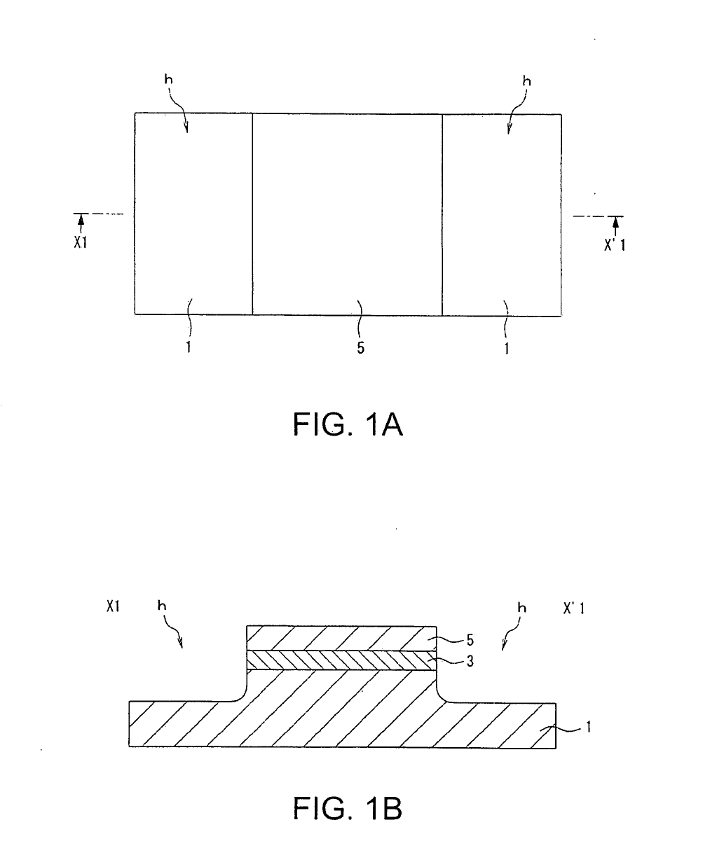

FIGS. 1A through 6B are diagrams showing a method for manufacturing a semiconductor device according to the embodiment of the invention. In FIGS. 1A through 6B, figures suffixed with the letter “A” are plan views. Figures suffixed with the letter “B” are sectional views respectively taken along the lines X1-X′1 to X6-X′6 of the figures suffixed with the letter “A”.

Referring to FIGS. 1A and 1B, a silicon germanium (SiGe) layer 3 and a Si layer 5 that have a single crystal structure are sequentially formed on a Si substrate 1 at first. The SiGe layer 3 and the Si layer 5 are formed in succession by epitaxial growth, for example.

Here, before the SiGe layer 3 is formed, a silicon buffer (Si-buffer) layer having a single crystal structure, which is not shown, may be thinly formed on the Si substrate 1, and then the SiGe layer 3 and the Si layer 5 are sequentially formed thereon. In this case, it is preferable that the Si-buffer layer, the SiGe layer 3, and the Si layer 5 be sequentially formed by epitaxial growth, for example. Film quality of a semiconductor film formed by epitaxial growth is largely affected by a crystalline state of a surface where the film is formed (that is, a foundation). Therefore, instead of directly forming the SiGe layer 3 on the Si substrate 1, the Si-buffer layer having less crystal defects than the surface of the Si substrate 1 is formed to interpose between the Si substrate 1 and the SiGe layer 3, enabling improvement of the film quality of the SiGe layer 3 (e.g. reduction of crystal defects).

Next, a part of the Si layer 5 and a part of the SiGe layer 3 in a region overlapping with an element isolation region (that is, a region where an SOI structure is not formed) in plan view are sequentially etched by photolithography and etching. According to the above, a support recess h is formed so as to penetrate the Si layer 5 and the SiGe layer 3 and reach the Si substrate 1 as its bottom. In the etching to form the support recess h, the support recess h may be etched until reaching the surface of the Si substrate 1, or the Si substrate 1 may be over etched so as to form a recessed portion as shown in FIG. 1B.

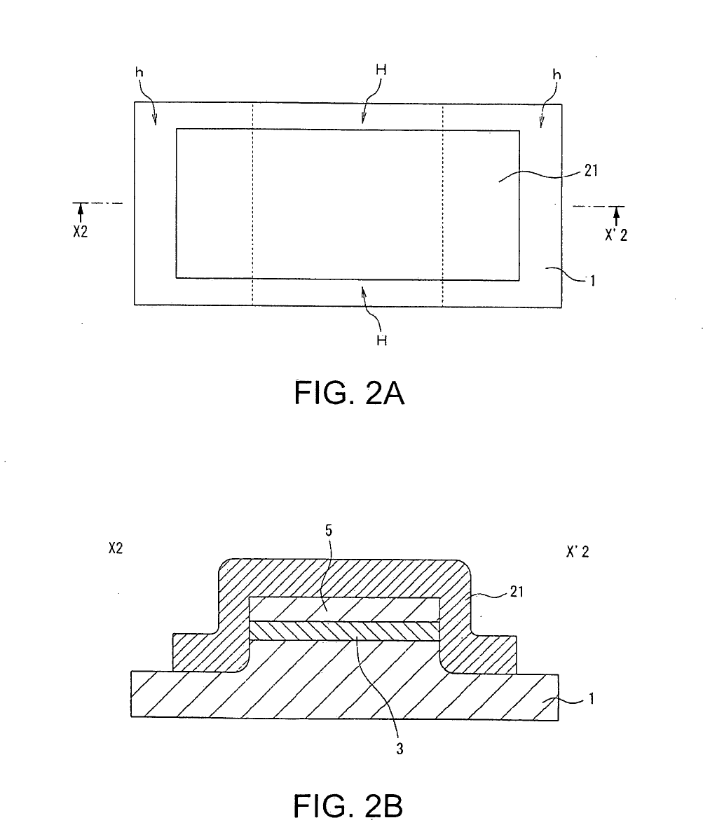

Next, a support film is formed on a whole surface of the Si substrate 1 so as to fill the support recess h. The support film is, for example, a SiO₂ film, and formed by CVD. Then, as shown in FIGS. 2A and 2B, a part of the support film, a part of the Si layer 5, and a part of the SiGe layer 3 that are in a region overlapping with the element isolation region in a plan view are sequentially etched by photolithography and etching, for example. Thus a support 21 is formed from the support film, while a groove H exposing each side of the Si layer 5 and the SiGe layer 3 and having the Si substrate 1 as its bottom is formed. Here, the groove H serves as an inlet of an etchant when the SiGe layer 3 is etched later.

In the etching to form the groove H, the SiGe layer 3 may be etched halfway to leave a part of the SiGe layer 3 on the Si substrate 1, or the Si substrate 1 may be over etched so as to form a recessed portion. In FIG. 2A, an element region (i.e. a region in which the SOI structure is formed) is defined as a region in a rectangular shape surrounded by the support recess h and the groove H in a plan view.

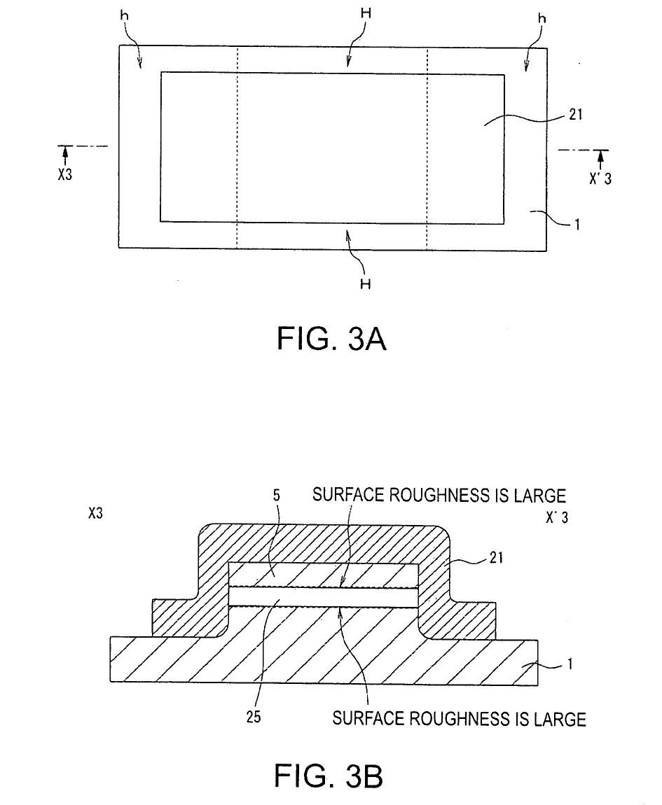

Then, a hydrofluoric-nitric acid solution, for example, is brought into contact with the respective sides of the SiGe layer 5 and the SiGe layer 3 through the groove H so as to selectively etch and remove the SiGe layer 3. Accordingly, a cavity 25 is formed between the Si layer 5 and the Si substrate 1 as shown in FIGS. 3A and 3B. In the wet etching with a hydrofluoric-nitric acid solution, since an etching rate of SiGe is higher than that of Si (that is, etching selectivity with respect to Si is high), only the SiGe layer 3 can be removed by etching while leaving the Si substrate 1 and the Si layer 5. From the middle of forming the cavity 25, the upper surface and the side surfaces of the Si layer 5 are supported by the support 21. In the removing the SiGe layer by using the hydrofluoric-nitric acid solution, the upper surface of the substrate 1 and the lower surface of the Si layer 5 that are facing the inside of the cavity 25 are also lightly etched with the hydrofluoric-nitric acid solution, causing a large surface roughness.

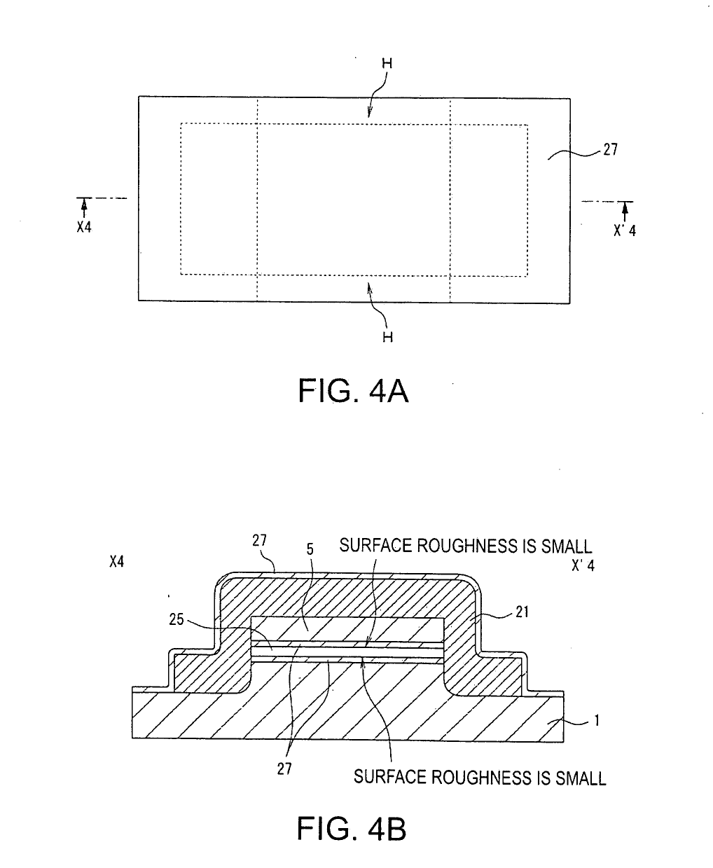

Next, as shown in FIGS. 4A and 4B, a Si layer 27 having an amorphous structure or a polycrystalline structure are thinly formed on the whole upper surface of the Si substrate 1 including an upper surface of the support 21, the upper surface of the Si substrate 1 and the lower surface of the Si layer 5 that are facing the inside of the cavity 25 respectively by CVD. Here, “thinly formed” means that the Si layer 27 is formed so as to have a film thickness to such an extent that the cavity 25 is not completely filled (that is, to leave a space). As shown in FIG. 4, a space is left in the cavity 25, enabling introduction of oxygen (O₂) or the like to the cavity 25, for example.

A treatment condition of CVD in order to form the Si layer 27 so as to have a film thickness to the extent in which the cavity 25 is not completely filled differs depending on a height of the inside of the cavity 25 (that is, a thickness of the cavity 25) before the Si layer 27 is formed. Therefore, it is preferable to conduct experimentation or a simulation prior to manufacturing a semiconductor device so as to derive an optimum condition for forming the Si layer 27 with respect to the thickness of the cavity 25.

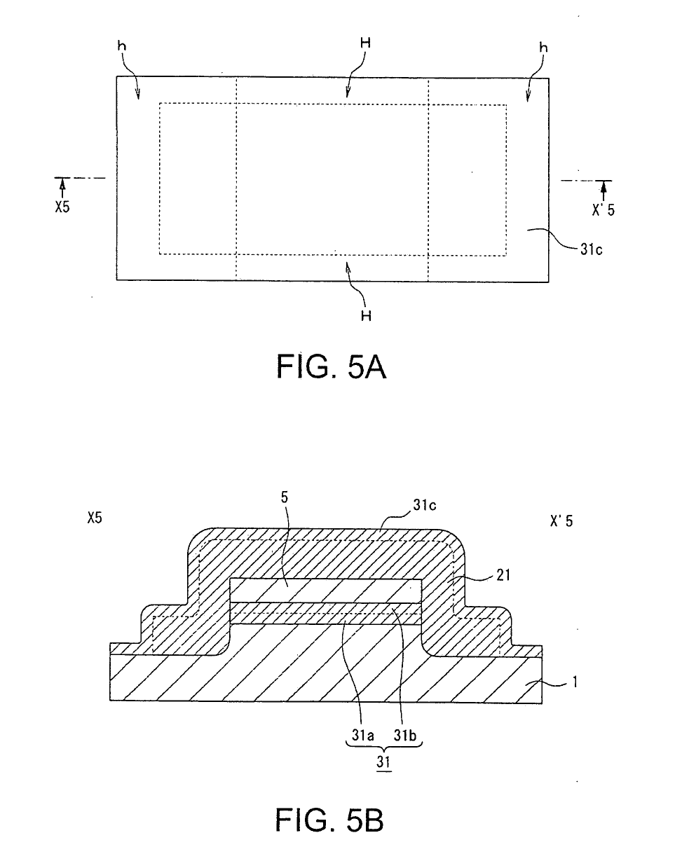

Next, the Si substrate 1 is placed in an oxidizing atmosphere of oxygen (O₂) or the like so as to thermally oxidize the Si substrate 1 and the Si layers 5 and 27, thereby forming a SiO₂ film 31 (hereinafter, also referred to as a BOX layer 31) in the cavity as shown in FIGS. 5A and 5B.

In the forming the BOX layer 31, the entire Si layer 27 formed on the whole of the upper surface of the Si substrate 1 (refer to FIGS. 4A and 4B) becomes a SiO₂ film 31c. Further, in the cavity 25, the Si layer 27 (refer to FIGS. 4A and 4B) is thermally oxidized first, and then the upper surface of the substrate 1 and the lower surface of the Si layer 5 are thermally oxidized successively. In the thermal oxidation as above, a SiO₂ film 31a grows upward from the Si substrate 1 while a SiO₂ film 31b grows downward from the Si layer 5 in the cavity 25. Then, the SiO₂ films 31a and 31b growing from upper and lower directions are attached to each other at about the center of the cavity 25.

Here, each surface of the SiO₂ film 31a and 31b is formed from the Si layer 27 by thermal oxidation. The Si layer 27 formed by CVD has a surface roughness that is smaller than those of the upper surface of the Si substrate 1 and the lower surface of the Si layer 5 after etching SiGe. Therefore, each surface of the SiO₂ films 31a and 31b formed by thermally oxidizing the Si layer 27 can also inherit the small surface roughness. Accordingly, the SiO₂ films 31a and 31b are attached to each other at about the center of the cavity 25.

Further, in the forming the BOX layer 31, the thermal oxidation progresses to not only the Si layer 27, but also the upper surface of the Si substrate 1 and the lower surface of the Si layer 5 that are covered with the Si layer 27, thereby respectively including a portion having a large roughness in the SiO₂ films 31a and 31b. Therefore, occurrence of dangling-bonds at an interface between the Si and SiO₂ is reduced, contributing to reducing an interface state density in the Si substrate 1 and the Si layer 5.

Further, a condition of the thermal oxidation that can attach the SiO₂ films 31a and 31b to each other and progress to the upper surface of the Si substrate 1 and the lower surface of the Si layer 5 in addition to the Si layer 27 differs depending on the thickness of the cavity 25 and the thickness of the Si layer 27 before the thermal oxidation. Therefore, it is preferable to conduct experimentation or a simulation prior to manufacturing a semiconductor device so as to derive optimal setting of a temperature, time, a gas to be used, a flow amount of the gas, and the like in order to obtain the result as above.

As shown in FIGS. 5A and 5B, after the BOX layer 31 is formed, an insulating film 33 is formed over the whole surface of the Si substrate 1 by CVD or the like so as to fill the support recess h and the groove H. The insulating film 33 is made of SiO₂, for example. Next, the insulating film 33 and the support 21 thereunder are planarized by CMP, for example, and further, wet etched with a dilute HF solution or the like.

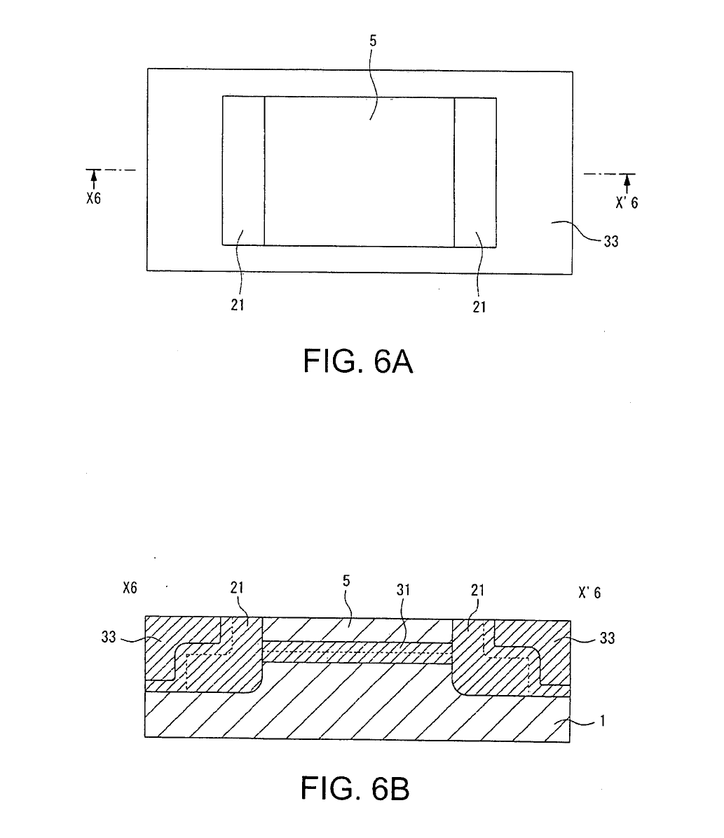

Accordingly, as shown in FIGS. 6A and 6B, the insulating film 33 or the like is thoroughly removed from the Si layer 5 (hereinafter, also referred to as the SOI layer 5), thereby completing the SOI structure composed of the BOX layer 31 and the SOI layer 5 in an SOI region on the Si substrate 1. A region other than the SOI region on the Si substrate 1 is filled with the insulating film 33 and the support 21, and serves as an element isolation layer. After the SOI structure is formed on the Si substrate 1, for example, a complete-depletion MOS transistor, a partial-depletion MOS transistor, or the like is formed on the SOI layer 5.

As the above, according to the embodiment of the invention, the upper surface of the Si substrate 1 and the lower surface of the Si layer 5 are covered with the Si layer 27 having a small surface roughness in the cavity 25. Therefore, in the forming the BOX layer 31, the Si layer 27 is thermally oxidized first to be the surfaces of the SiO₂ films 31a and 31b. According to the above, both surface roughnesses of the SiO₂ film 31a growing upward from the Si substrate 1 and the SiO₂ film 31b growing downward from the Si layer 5 are reduced, resulting in favorable attachment of the SiO₂ films 31a and 31b growing from the upper and lower directions in the cavity 25. Therefore, for example, in CMP to expose the surface of the SOI layer 5, wet etching with a dilute HF solution, and the like, the SiO₂ film 31b is prevented from being detached from the SiO₂ film 31a, and further the SOI layer 5 formed thereon is prevented from being detached from the Si substrate 1 by accompanying with the SiO₂ film 31b.

Consequently, a method for a semiconductor device with high reliability can be provided.

In the embodiment, the Si substrate 1 corresponds to a “semiconductor substrate”, the SiGe layer 3 corresponds to a “first semiconductor layer”, and the Si layer 5 corresponds to a “second semiconductor layer” and a “first silicon layer” of the invention. Further, the support recess h corresponds to a “second groove” and the grove H corresponds to a “first groove” of the invention. Furthermore, the Si layer 27 corresponds to a “third semiconductor layer” and a “second silicon layer” of the invention, and the SiO₂ film (BOX layer) 31 corresponds to a “buried oxide film” of the invention.

What is claimed is:

1. A method for manufacturing a semiconductor device, comprising:
a) forming a first semiconductor layer on a semiconductor substrate;
b) forming a second semiconductor layer on the first semiconductor layer;
c) forming a first groove exposing a side of the first semiconductor layer by partially etching the first semiconductor layer and the second semiconductor layer;
d) forming a cavity between the semiconductor substrate and the second semiconductor layer by etching the first semiconductor layer through the first groove under an etching condition in which the first semiconductor layer is more easily etched than the second semiconductor layer;
e) respectively forming a third semiconductor layer on an upper surface of the semiconductor substrate and a lower surface of the second semiconductor layer that are facing an inside of the cavity while leaving a space in the cavity; and
f) thermally oxidizing the third semiconductor layer so as to form a buried oxide film in the cavity.

2. The method for manufacturing a semiconductor device according to claim 1, further comprising between the step b) and the step d):
partially etching the second semiconductor layer and the first semiconductor layer so as to form a second groove penetrating the second semiconductor layer and the first semiconductor layer; and
forming a support to support the second semiconductor layer at least in the second groove.

3. The method for manufacturing a semiconductor device according to claim 1, wherein the step f) further comprising thermally oxidizing the upper surface of the semiconductor substrate and the lower surface of the second semiconductor layer that are covered with the third semiconductor layer so as to form the buried oxide film in addition to thermally oxidizing the third semiconductor layer.

4. The method for manufacturing a semiconductor device :according to claim 1, wherein the semiconductor substrate is made of silicon, and the step b) includes forming a first silicon layer having a single crystalline structure by epitaxial growth as the second semiconductor layer, while the step e) includes forming a second silicon layer having one of an amorphous structure and a polycrystalline structure by chemical vapor deposition as the third semiconductor layer.
